(19) United States
(12) Patent Application Publication
(10) Pub. No.: US 2025/0291259 A1
(43) Pub. Date: Sep. 18, 2025

(54) METHOD OF MANUFACTURING SEMICONDUCTOR DEVICE

(71) Applicant: SAMSUNG ELECTRONICS CO., LTD., Suwon-si (KR)

(72) Inventors: Jeongjin LEE, Suwon-si (KR); Inho KWAK, Suwon-si (KR); Chan HWANG, Suwon-si (KR)

(73) Assignee: SAMSUNG ELECTRONICS CO., LTD., Suwon-si (KR)

(21) Appl. No.: 19/007,073

(22) Filed: Dec. 31, 2024

(30) Foreign Application Priority Data
Mar. 13, 2024 (KR) 10-2024-0035425

(51) Int. Cl. G03F 7/00; G03F 9/00

(52) U.S. Cl. CPC G03F 7/70516; G03F 7/70033; G03F 7/70358; G03F 9/7019

(57) ABSTRACT

Provided is a system and method of manufacturing a semiconductor device. The method includes: dividing a wafer into a plurality of fields arranged in rows and columns; measuring an overlay error of a pattern in each of the plurality of fields and collecting overlay error data; and correcting the overlay error of the pattern in a first field among the plurality of fields, wherein the correcting the overlay error of the pattern in the first field includes: dividing the first field into first and second regions, wherein the overlay error of the second region is greater than an overlay error of the first region; comparing the overlay error of the first and second regions; defining a first weight for the first region and a second weight for the second region; obtaining a correction parameter by executing regression using the overlay error data; and providing the correction parameter to a scanner.

### CROSS-REFERENCE TO RELATED APPLICATION

This application is based on and claims priority to Korean Patent Application No. 10-2024-0035425, filed on Mar. 13, 2024, in the Korean Intellectual Property Office, the disclosure of which is incorporated by reference herein in its entirety.

### BACKGROUND

### 1. Field

The disclosure relates to a method of manufacturing a semiconductor device.

### 2. Description of Related Art

As the size of memory cells has recently been reduced for the high integration of information and communication devices, the complexity of operating circuits and/or wiring structures, which are included in memory devices for the operations and electrical connection of semiconductor devices, has increased. Accordingly, extreme ultraviolet (EUV) lithography is increasingly applied to the manufacture of semiconductor devices. EUV lithography is a lithography technique that uses light having a wavelength in a range of about 4 nm to about 124 nm, preferably, light having a wavelength of 13.5 nm, and enables sub-20 nm ultrafine dimensional processing, which is difficult to implement with a lithography technique using ArF excimer laser light. A feedback process through overlay measurement and analysis is one of the key factors that secure the reliability of EUV lithography. Accordingly, there is a need to increase the accuracy and reliability of overlay measurement.

### SUMMARY

Provided is a method of manufacturing a semiconductor device.

According to an aspect of the disclosure, a method of manufacturing a semiconductor device includes: dividing a wafer into a plurality of fields, wherein the plurality of fields are arranged in rows and columns; measuring an overlay error of a pattern in each of the plurality of fields and collecting overlay error data; and correcting the overlay error of the pattern in a first field among the plurality of fields, wherein the correcting the overlay error of the pattern in the first field includes: dividing the first field into a first region and a second region, wherein the second region has an overlay error that is greater than an overlay error of the first region; comparing the overlay error of the first region with the overlay error of the second region; defining a first weight for the first region and a second weight for the second region; obtaining a correction parameter by executing regression using the overlay error data; and providing the correction parameter to a scanner.

According to an aspect of the disclosure, a method of manufacturing a semiconductor device includes: dividing a wafer into a plurality of fields, wherein the plurality of fields are arranged in rows and columns; measuring an overlay error of a pattern in each of the plurality of fields and collecting overlay error data; and correcting the overlay error of the pattern in a first field among the plurality of fields, wherein the correcting of the overlay error of the pattern in the first field includes: dividing the first field into N regions, where N is an integer of at least 2; comparing overlay errors of the N regions with each other; defining N weights for the N regions, respectively; obtaining a first correction parameter by executing regression using the overlay error data; and providing the first correction parameter to a scanner.

According to an aspect of the disclosure, a method of manufacturing a semiconductor device includes: dividing a wafer into a plurality of fields, wherein the plurality of fields are arranged in rows and columns; measuring an overlay error of a pattern in each of the plurality of fields and collecting overlay error data; and correcting the overlay error of the pattern in a first field among the plurality of fields, wherein the correcting the overlay error of the pattern in the first field includes: dividing the first field into a first region and a second region, wherein the second region has an overlay error that is greater than an overlay error of the first region; identifying whether the overlay error of the second region is greater than an overlay error limit; based on identifying that the overlay error of the second region is greater than the overlay error limit, comparing the overlay error of the first region with the overlay error of the second region and defining a first weight for the first region and a second weight for the second region; obtaining a first correction parameter by executing regression using the overlay error data; and providing the first correction parameter to a scanner, and wherein the first correction parameter is defined as

$${β}_{1} = {( {w}_{1}^{2} {X}_{1}^{T} {X}_{1} + {w}_{2}^{2} {X}_{2}^{T} {X}_{2} )}^{- 1} ( {w}_{1}^{2} {X}_{1}^{T} {Y}_{1} + {w}_{2}^{2} {X}_{2}^{T} {Y}_{2} ) ,$$

where β₁ is the first correction parameter, X₁ is a first unit point in the first region, X₂ is a second unit point in the second region, w₁ is the first weight, w₂ is the second weight, Y₁ is an overlay error at the first unit point, and Y₂ is an overlay error at the second unit point.

### BRIEF DESCRIPTION OF DRAWINGS

The above and other aspects and features of certain embodiments of the present disclosure will be more apparent from the following description taken in conjunction with the accompanying drawings, in which:

FIG. 1 is a flowchart of a method of manufacturing a semiconductor device, according to an embodiment;

FIG. 2 is a detailed flowchart of an operation of correcting an overlay with respect to a pattern in a first field among a plurality of fields;

FIGS. 3A, 3B and 3C are schematic diagrams illustrating a method of manufacturing a semiconductor device, according to an embodiment;

FIGS. 4A, 4B and 4C are conceptual diagrams illustrating overlay correction parameters;

FIGS. 5A, 5B and 5C are graphs illustrating overlay correction when weight differentiation for each region of a pattern is not used;

FIGS. 6A, 6B and 6C are graphs illustrating overlay correction when weight differentiation for each region of a pattern is used;

FIG. 7 is a diagram illustrating overlay data obtained by measuring an overlay of a wafer;

FIGS. 8A, 8B and 8C are diagrams illustrating overlay correction results when weight differentiation for each region of a pattern is not used;

FIGS. 9A, 9B and 9C are diagrams illustrating overlay correction results when weight differentiation for each region of a pattern is used;

FIGS. 10 and 11 are graphs illustrating effects of a method of manufacturing a semiconductor device, according to an embodiment;

FIG. 12 is a flowchart of a method of manufacturing a semiconductor device, according to an embodiment;

FIG. 13 is a detailed flowchart of an operation in the method of FIG. 12;

FIG. 14 is a flowchart of a method of manufacturing a semiconductor device, according to an embodiment;

FIG. 15 is a block diagram of a scanner system according to an embodiment; and

FIG. 16 is a detailed block diagram of a scanner in FIG. 15.

### DETAILED DESCRIPTION

Hereinafter, embodiments are described in detail with reference to the accompanying drawings. However, the disclosure should not be construed as being limited to the embodiments and may be embodied in other various forms. The embodiments are provided to fully convey the scope of the disclosure to those skilled in the art rather than to allow the disclosure to be fully completed.

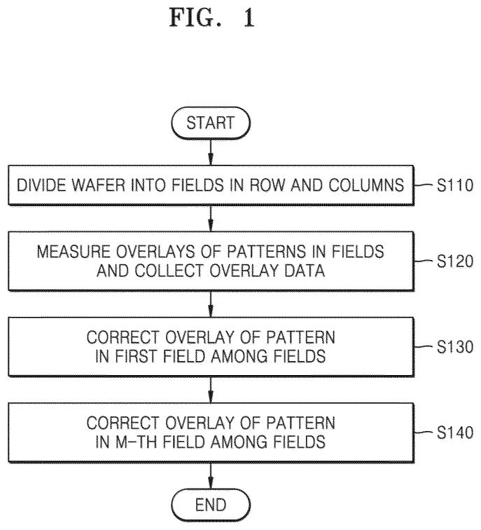

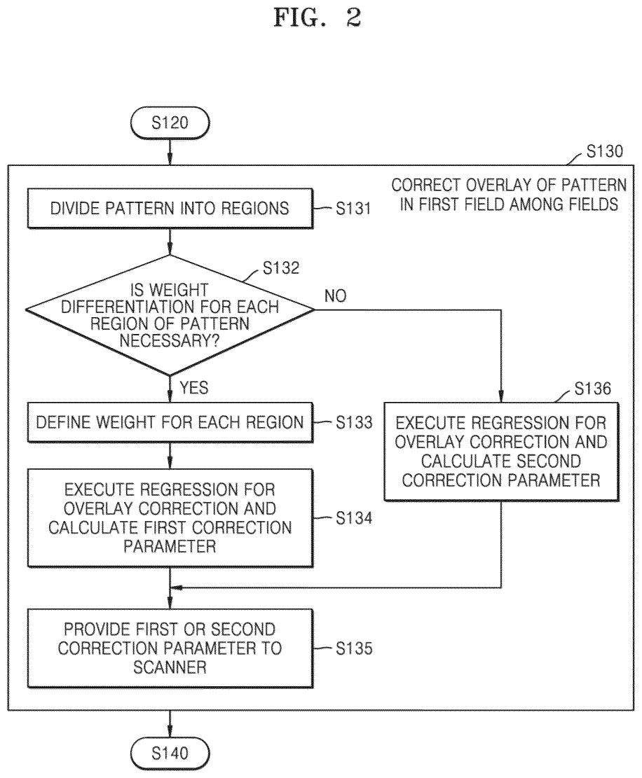

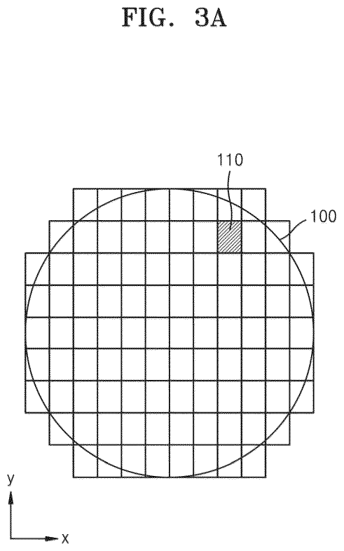

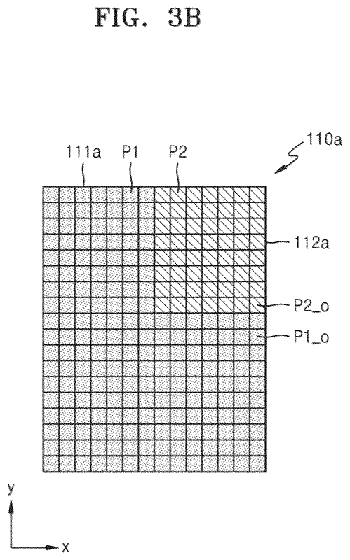

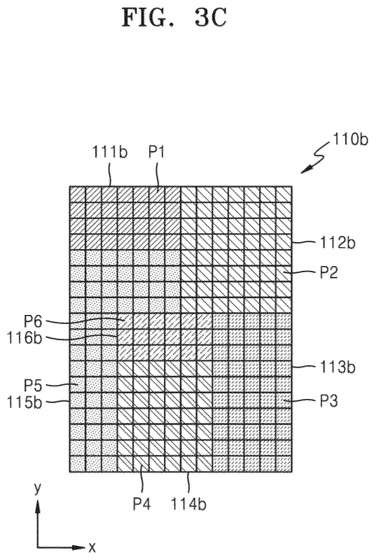

FIG. 1 is a flowchart of a method of manufacturing a semiconductor device, according to an embodiment. FIG. 2 is a detailed flowchart of an operation of correcting an overlay with respect to a pattern in a first field among a plurality of fields. FIGS. 3A to 3C are schematic diagrams illustrating a method of manufacturing a semiconductor device, according to an embodiment. Descriptions are made below with reference to FIGS. 1 to 3C.

Referring to FIGS. 1 and 3A, according to an embodiment, a method of manufacturing a semiconductor device may include operation S110 in which a wafer 100 is divided into fields 110 in rows and columns. At this time, the wafer 100 may include a wafer, such as a silicon wafer, which is used to manufacture semiconductor devices. In one or more embodiments, the wafer 100 may include a layer which has a pattern. The pattern may include various arrangement marks which are designed for alignment monitoring and overlay inspection. In one or more embodiments, the layer may include, but is not limited to, a semiconductor material layer such as a silicon (Si) layer or a silicon germanium (SiGe) layer, a dielectric material layer such as an interlayer dielectric (ILD) layer, or a conductive material layer such as a doped silicon layer.

The fields 110 in rows and columns may be defined on the wafer 100. Each of the fields 110 may correspond to an exposure region exposed by a photomask and may include a pattern for a single chip or multiple chips. In one or more embodiments, a resist layer in one of the fields 110 may be exposed to an exposure device by a photomask, and a resist layer in a next field 110 along a scan path is subsequently exposed to the exposure device by the photomask.

Thereafter, the method of manufacturing a semiconductor device may include operation S120 in which an overlay is measured with respect to patterns in each of the fields 110 and overlay data is collected. Here, an overlay refers to the degree of overlap between a pattern of an under layer and a pattern of an upper layer. As used herein, the term “overlay” may also be referred to as an “overlay error,” but the term “overlay” is used herein for convenience of description. In general, during an exposure of an upper layer, an overlay is minimized by performing a shot on the upper layer after aligning as much as possible the upper layer with an under layer based on the overlay marks of the under layer. Nevertheless, when an overlay is large, that is, when the relative positional difference between an under layer pattern and a current layer pattern is large, the large overlay may adversely affect the performance of a semiconductor device and ultimately lead to a defect in the semiconductor device.

An overlay may be calculated by measuring a first overlay mark on an under layer and a second overlay mark on an upper layer and calculating a relative positional difference between the first overlay mark and the second overlay mark. An overlay mark may be formed as a box pattern or a bar pattern in a scribe lane of a wafer. However, the shape or position of an overlay mark is not limited to those described above.

Overlays may occur for a variety of reasons. For example, an overlay may occur due to a field error of a shot during photolithography by a scanner. The overlay caused by a field error of a shot may be resolved by overlay control or correction by the scanner that performs the photolithography. For example, the overlay correction by the scanner may be carried out by adjusting a lens actuator in a stage or an optical system. As described above, overlay correction, i.e., the field correction of a shot, may be performed by a scanner during photolithography.

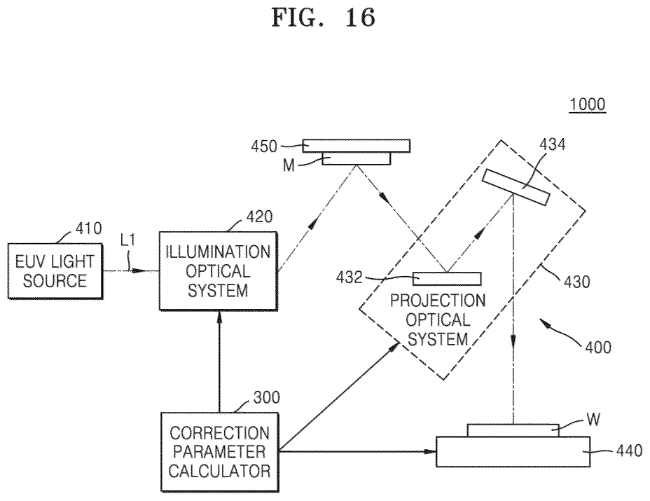

In detail, overlay correction by a scanner may be carried out by the physical operation of the scanner. Here, the physical operation may include applying pressure to or tilting a lens or moving a lens quickly. The physical operation for the overlay correction by a scanner may also include moving a patterning target (W in FIG. 16, e.g., a wafer) by using a stage (440 in FIG. 16) or heating the patterning target.

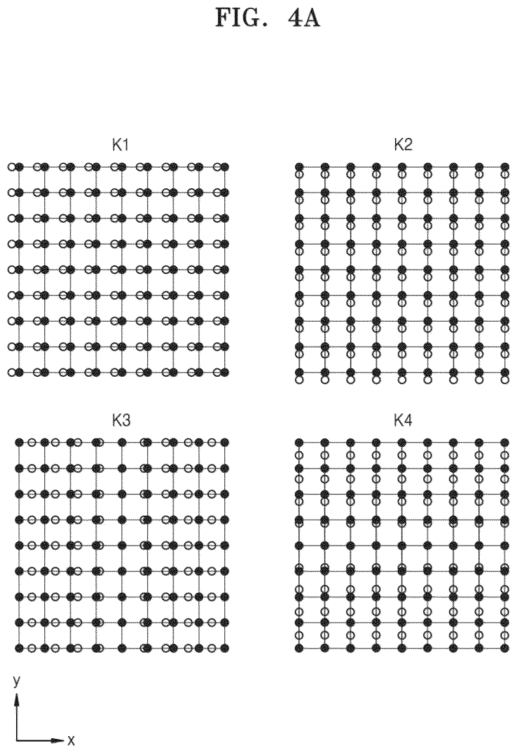

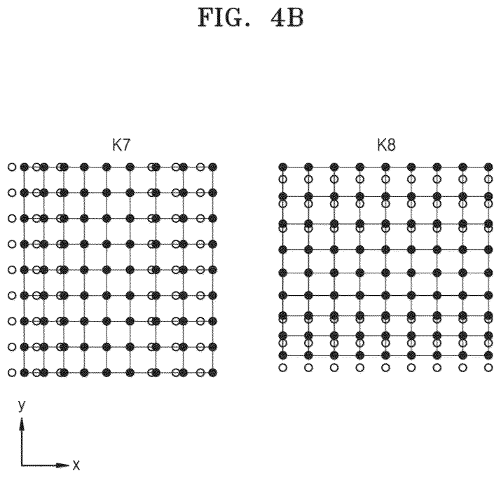

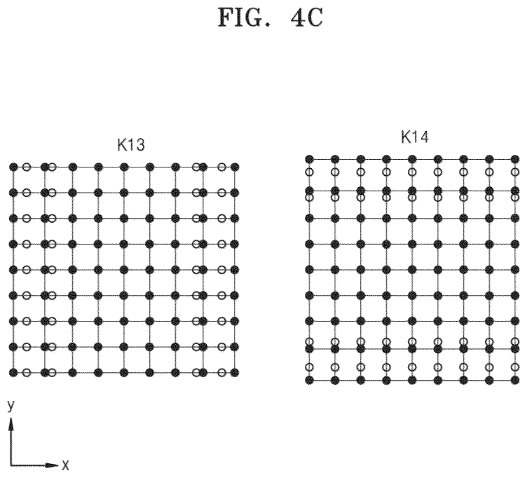

Overlay correction parameters may be distinguished in various manners. The correction limits of a scanner may vary with overlay correction parameters. For example, in the case of an extreme ultraviolet (EUV) scanner, overlay correction parameters may range from K1 to K20, and the correction limits of the EUV scanner may be different with respect to the overlay correction parameters. The number of overlay correction parameters is not limited to 20 in an EUV scanner. For example, there may be more than 20 overlay correction parameters in an EUV scanner. The overlay correction method of the present embodiment may not be limited to an EUV scanner and may also be applied to other types of scanners. For example, the overlay correction method may be applied to various types of scanners, such as an immersion scanner and an extended scanner. The overlay correction parameters are described in detail with reference to FIGS. 4A to 4C below.

Thereafter, the method of manufacturing a semiconductor device may include operation S130 in which an overlay of a pattern in a first field 110a among the fields 110 is corrected. The detailed descriptions of this are given below. Thereafter, the method of manufacturing a semiconductor device includes operation S140 in which an overlay of a pattern in an M-th field among the fields 110 is corrected. Here, M is an integer of at least 2. A method of correcting the overlay of the pattern in the M-th field may be substantially the same as the method of correcting the overlay of the pattern in the first field 110a.

Referring to FIG. 2, a method of correcting the overlay of the pattern in the first field 110a among the fields, i.e., operation S130, may include dividing the pattern into regions in operation S131. FIG. 3B illustrates the first field 110a in a method of manufacturing a semiconductor device, according to an embodiment. Here, the first field 110a may be divided into a first region 111a and a second region 112a. For example, the second region 112a may be an outer region that is further away from the center of the wafer 100 than the first region 111a. The first region 111a may be constituted of a plurality of first unit points P1 and the second region 112a may be constituted of a plurality of second unit points P2. The first unit points P1 and the second unit points P2 may each be the minimum unit point at which an overlay is measured using an overlay measuring device. Unit points in the outermost part of the first region 111a among the first unit points P1 of the first region 111a may be defined as first outermost unit points P1_o. Unit points in the outermost part of the second region 112a among the second unit points P2 of the second region 112a may be defined as second outermost unit points P2_o. One of the first outermost unit points P1_o may be in contact with one of the second outermost unit points P2_o. In other words, the first field 110a may be constituted of only the first region 111a and the second region 112a without an empty space (e.g., an empty point).

According to an embodiment, the method of manufacturing a semiconductor device may include determining whether a different weight is required for each region of the pattern in the first field 110a in operation S132. When the difference between an overlay measured in the first region 111a and an overlay measured in the second region 112a is not large, weight differentiation for each region of the pattern may not be necessary. For example, as the second region 112a is further away from the center of the wafer 100 than the first region 111a, the second region 112a may have larger overlay data than the first region 111a. When the overlay of the second region 112a is greater than a preset overlay limit, it may be determined that weight differentiation for each region of the pattern is necessary. When the overlay of the second region 112a is less than the overlay limit, it may be determined that weight differentiation for each region of the pattern is not necessary. This is just an example. The first region 111a may have larger overlay data than the second region 112a in other examples. In these examples, it may be determined that weight differentiation for each region of the pattern is necessary when the overlay of the first region 111a is greater than the overlay limit. When the overlay of the first region 111a is less than the overlay limit, it may be determined that weight differentiation for each region of the pattern is not necessary. In other words, the overlay limit may be a value based on which whether weight differentiation for each region of the pattern is necessary is determined.

According to an embodiment, the method of manufacturing a semiconductor device may include defining a weight for each region of the first field 110a in operation S133. A weight for the first region 111a of the first field 110a may be defined as w₁ and a weight for the second region 112a of the first field 110a may be defined as w₂. A weight may be a coefficient representing a relative importance. When a second weight for the second region 112a is large, the importance of a correction parameter for the second region 112a may increase. When a first weight for the first region 111a is large, the importance of a correction parameter for the first region 111a may increase.

According to an embodiment, the method of manufacturing a semiconductor device may include calculating a first correction parameter by executing regression for overlay correction in operation S134. Regression or regression analysis may refer to an analysis method in which the accuracy of fit is measured after a model between two variables is obtained with respect to a plurality of pieces of collected data.

Regression may be divided into linear regression and non-linear regression according to the relationship between variables and may be classified into simple regression, multiple regression, and higher-order regression according to the number of variables. Regression may be explained below using simple linear regression that is the simplest.

When the overlay residual of the first region 111a is expressed as e₁=Y₁-X₁β and the overlay residual of the second region 112a is expressed as e₂=Y₂-X₂β, X is an independent variable and denotes a unit point in the first region 111a or the second region 112a, Y is a dependent variable and denotes an overlay at the unit point, and β denotes a correction parameter. In addition, e is overlay residual and denotes the difference between a real overlay value y and a predicted overlay value ŷ obtained from a regression equation.

The simple linear regression is a process of finding β that minimizes the mean square error (MSE) of the difference, e, between the real overlay value y and the predicted overlay value y obtained from a regression equation. In other words, the simple linear regression is a process of finding β that minimizes the MSE in an equation expressed as MSE(β)=w₁²Σe₁²+w₂²Σ e₂². In regression, the MSE is referred to as cost or a cost function. Here, w₁ may denote a first weight and w₂ may denote a second weight.

$$MSE ( β ) = {{w}_{1}^{2} ( {Y}_{1} - {X}_{1} β )}^{T} ( {Y}_{1} - {X}_{1} β ) + {{w}_{2}^{2} ( {Y}_{2} - {X}_{2} β )}^{T} ( {Y}_{2} - {X}_{2} β ) . \qquad Equation 1$$

The MSE may be expressed as set forth in Equation 1. Here, to find β that minimizes the MSE, the value of β that gives 0 as a result of partially differentiating the MSE with respect to β may be obtained.

$$β = {( {w}_{1}^{2} {X}_{1}^{T} {X}_{1} + {w}_{2}^{2} {X}_{2}^{T} {X}_{2} )}^{- 1} ( {w}_{1}^{2} {X}_{1}^{T} {X}_{1} + {w}_{2}^{2} {X}_{2}^{T} {X}_{2} ) . \qquad Equation 2$$

In the process of obtaining the value of β that gives 0 as the result of partially differentiating the MSE with respect to β, β may be obtained using Equation 2. Here, the value of β in Equation 2 may be defined as the first correction parameter.

Overfitting may often occur in regression. Overfitting may mean that the generalizing ability of a model is decreased by analyzing the relationship between the collected data values in more detail and complexity than necessary. Overfitting is described in detail with reference to FIGS. 4A to 4C below.

Thereafter, according to an embodiment, the method of manufacturing a semiconductor device may include providing the first correction parameter to a scanner (400 in FIG. 16) in operation S135. The scanner (400 in FIG. 16) may execute overlay correction based on the first correction parameter in an exposure process.

FIG. 3C illustrates a first field 110b in a method of manufacturing a semiconductor device, according to one or more embodiments. In an operation of dividing a pattern into regions, the first field 110b may be divided into N regions. Referring to FIG. 3C, the first field 110b may be divided into six regions, i.e., N=6. A first region 111b may be constituted of a plurality of first unit points P1, a second region 112b may be constituted of a plurality of second unit points P2, a third region 113b may be constituted of a plurality of third unit points P3, a fourth region 114b may be constituted of a plurality of fourth unit points P4, a fifth region 115b may be constituted of a plurality of fifth unit points P5, and a sixth region 116b may be constituted of a plurality of sixth unit points P6. The first to sixth unit points P1 to P6 may each be the minimum unit point at which an overlay is measured using an overlay measuring device. The first field 110b may be constituted of only the first to sixth regions 111b to 116b without an empty space (e.g., an empty point). The first field 110b constituted of six regions is just an example. The first field 110b may be constituted of N regions, where N is an integer of at least 2.

In operation S133 in which a weight is defined for each region of the first field 110b, weights for the first to sixth regions 111b to 116b, respectively, may be defined as w₁, w₂, w₃, w₄, w₅, and w₆. The weights for the first to sixth regions 111b to 116b are substantially the same as the weight for the first and second regions 111a and 112a described with reference to FIG. 3B, and thus, detailed descriptions thereof are omitted.

In operation S132 in which whether weight differentiation for each region of a pattern in the first field 110b is necessary is determined, it may be determined that weight differentiation for each region of the pattern is necessary when the overlay of the second region 112b is greater than the overlay limit (in the case where the overlay of the second region 112b is the largest among the overlays of the first to sixth regions 111b to 116b). At this time, the method of manufacturing a semiconductor device may include calculating the first correction parameter by executing regression for overlay correction.

$$MSE ( β ) = {\sum }_{i = 1}^{n} {{w}_{i}^{2} ( {Y}_{i} - {X}_{i} β )}^{T} ( {Y}_{i} - {X}_{i} β ) . \qquad Equation 3$$

The MSE may be expressed as set forth in Equation 3, where “n” is an integer of at least 2. In the present embodiment, n=6. Here, to find β that minimizes the MSE, the value of β that gives 0 as a result of partially differentiating the MSE with respect to β may be obtained.

$$β = {( {\sum }_{i = 1}^{n} {w}_{i}^{2} {X}_{i}^{T} {X}_{i} )}^{- 1} ( {\sum }_{i = 1}^{n} {w}_{i}^{2} {X}_{i}^{T} {Y}_{i} ) . \qquad Equation 4$$

In the process of obtaining the value of β that gives 0 as the result of partially differentiating the MSE with respect to β, β may be obtained using Equation 4. Here, the value of β in Equation 4 may be defined as the first correction parameter.

Thereafter, according to an embodiment, the method of manufacturing a semiconductor device may include providing the first correction parameter to the scanner (400 in FIG. 16) in operation S135. The scanner (400 in FIG. 16) may execute the overlay correction based on the first correction parameter in an exposure process.

In operation S132 in which it is determined whether weight differentiation for each region of the pattern in the first field 110a is necessary, it may be determined that weight differentiation for each region of the pattern is not necessary when the overlay of the second region 112a is less than the overlay limit (in the case where the overlay of the second region 112a is greater than the overlay of the first region 111a). The method of manufacturing a semiconductor device may include calculating a second correction parameter by executing regression for overlay correction in operation S136. The second correction parameter may be different from the first correction parameter.

FIG. 3B is also referred to in descriptions below. A process of finding β that minimizes the MSE in MSE(β)=Σe² may be performed. Here, the second correction parameter, B, does not consider a weight for each of the first region 111a and the second region 111b and is a parameter in which the same weight is applied to the entire first field 110a.

$$MSE ( β ) = {( Y - X β )}^{T} ( Y - X β ) . \qquad Equation 5$$

The MSE may be expressed as set forth in Equation 5. Here, to find the second correction parameter, β, that minimizes the MSE, the value of β that gives 0 as a result of partially differentiating the MSE with respect to β may be obtained.

$$β = {( {X}^{T} X )}^{- 1} {X}^{T} Y . \qquad Equation 6$$

In the process of obtaining the value of β that gives 0 as the result of partially differentiating the MSE with respect to β, β may be obtained using Equation 6. Here, the value of β in Equation 6 may be defined as the second correction parameter.

Thereafter, according to an embodiment, the method of manufacturing a semiconductor device may include providing the second correction parameter to the scanner (400 in FIG. 16) in operation S135. The scanner (400 in FIG. 16) may execute the overlay correction based on the second correction parameter in an exposure process.

According to an embodiment, the method of manufacturing a semiconductor device may include correcting the overlay of the pattern in the M-th field among a plurality of fields in operation S140 after correcting the overlay of the pattern in the first field among the fields in operation S130. Here, M is an integer of at least 2. Operation S140 in which the overlay of the pattern in the M-th field is corrected may be substantially the same as operation S130 in which the overlay of the pattern in the first field 110a is corrected, except that a field undergoing overlay correction is changed. Thus, detailed descriptions thereof are omitted.

According to the disclosure, a method of manufacturing a semiconductor device may include dividing the wafer 100 into a plurality of fields (e.g., 110 in FIG. 3A) in rows and columns. Thereafter, each of the fields (110 in FIG. 3A) may be divided into a plurality of regions (e.g., 111a and 112a in FIG. 3B), and a determination of whether weight differentiation for a correction parameter is necessary with respect to each region (111a or 112a in FIG. 3B) may be obtained. When weight differentiation for a correction parameter is necessary, regression for overlay correction may be executed and a first correction parameter including a plurality of weights may be calculated. As described above, when each field (110 in FIG. 3A) is divided into a plurality of regions (111a and 112a in FIG. 3B) and weights are differentiated for a correction parameter, flexible response may be possible in the case where there is a high need for overlay correction in a particular region.

FIGS. 4A to 4C are conceptual diagrams illustrating overlay correction parameters.

FIG. 4A illustrates linear correction parameters corresponding to first-order correction parameters among the overlay correction parameters. In detail, a K1 correction parameter in the upper left may correspond to the case where an overlay of a constant size occurs on one side of a first direction (an X direction), and a K2 correction parameter may correspond to a case where an overlay of a constant size occurs on one side of a second direction (a Y direction). When an overlay in the first direction (the X direction) is dx and an overlay in the second direction (the Y direction) is dy, the K1 correction parameter may be expressed as dx=k1 and the K2 correction parameter may be expressed as dy=k2. Here, the first direction (the X direction) may be a direction in which a slit below an EUV mask (M in FIG. 16) extends, and the second direction (the Y direction) may correspond to a scan direction in an EUV exposure process and may be perpendicular to the first direction (the X direction).

A K3 correction parameter in the lower left may correspond to the case where an overlay error of a size proportional to the position along the first direction (the X direction) occurs on the both sides of the first direction (the X direction), and a K4 correction parameter in the lower right may correspond to the case where an overlay error of a size proportional to the position along the second direction (the Y direction) occurs on the both sides of the second direction (the Y direction). Accordingly, the K3 correction parameter may be expressed as dx=k3*x and the K4 correction parameter may be expressed as dy=k4*y.

There may also be a K5 correction parameter and a K6 correction parameter as linear correction parameters other than the K1 to K4 correction parameters, wherein the K5 correction parameter may be expressed as dx=k5*y and the K6 correction parameter may be expressed as dy=k6*x.

FIG. 4B illustrates second-order correction parameters among the overlay correction parameters. In detail, a K7 correction parameter in the left may correspond to the case where an overlay error of a size proportional to the square of the position along the first direction (the X direction) occurs on the both sides of the first direction (the X direction), and a K8 correction parameter in the right may correspond to the case where an overlay error of a size proportional to the square of the position along the second direction (the Y direction) occurs on the both sides of the second direction (the Y direction). Accordingly, the K7 correction parameter may be expressed as dx=k7*x² and the K8 correction parameter may be expressed as dy=k8*y².

There may also be K9 to K12 correction parameters as second-order correction parameters other than the K7 and K8 correction parameters, wherein the K9 correction parameter may be expressed as dx=k9*x*y, the K10 correction parameter may be expressed as dy=k10*y*x, the K11 correction parameter may be expressed as dx=k11*y², and the K12 correction parameter may be expressed as dy=k12*x².

FIG. 4C illustrates third-order correction parameters among the overlay correction parameters. In detail, a K13 correction parameter, shown on the left of FIG. 4C, may correspond to a case where an overlay error of a size proportional to the cube of the position along the first direction (the X direction) occurs on the both sides of the first direction (the X direction), and a K14 correction parameter, shown on the right of FIG. 4C, may correspond to a case where an overlay error of a size proportional to the cube of the position along the second direction (the Y direction) occurs on the both sides of the second direction (the Y direction). Accordingly, the K13 correction parameter may be expressed as dx=k13*x³ and the K14 correction parameter may be expressed as dy=k14*y³.

There may also be K15 to K20 correction parameters as third-order correction parameters other than the K13 and K14 correction parameters, wherein the K15 correction parameter may be expressed as dx=k15*x²*y, the K16 correction parameter may be expressed as dy=k16*y²*x, the K17 correction parameter may be expressed as dx=k17*x*y², the K18 correction parameter may be expressed as dy=k18*y*x², the K19 correction parameter may be expressed as dx=k19*y³, and the K20 correction parameter may be expressed as dy=k20*x³.

As described above, the correction limit of a scanner may vary with correction parameters. In the case of an EUV scanner and the K1 to K6 correction parameters corresponding to linear correction parameters, the correction limit is at least 1000 nm per cm, which may be seen that there is almost no limit. In other words, because the K1 to K6 correction parameters calculated through regression fall below the correction limit of the scanner without any need for comparison, there is no need to consider regulated regression. With respect to the K8, K10, K11, K14, K16, and K19 correction parameters among the second and third-order correction parameters, the correction limit is about 1000 nm per cm² or cm³, and accordingly, there is no need to significantly consider the correction limit. In the case of the other higher-order correction parameters, the correction limit of the scanner is about 10 nm per cm² or cm³. Accordingly, the correction parameters calculated through regression may be compared with the correction limit of the scanner. When a correction parameter exceeds the correction limit, regulated regression may be executed to newly calculate the correction parameter.

An embodiment including an EUV scanner has been described above. Like the embodiment including an EUV scanner, in an embodiment including an immersion scanner or an extended scanner, the correction limit is very small with respect to some higher-order correction parameters, and accordingly, the correction parameters falling below the correction limit may be calculated through regulated regression.

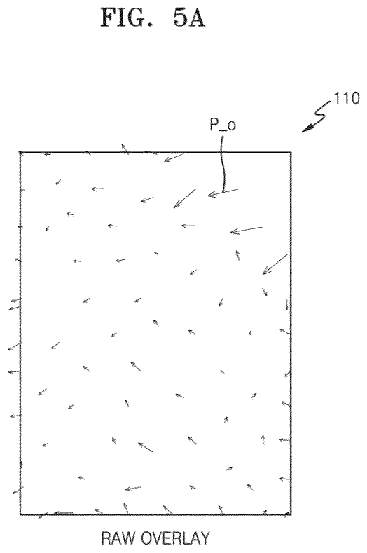

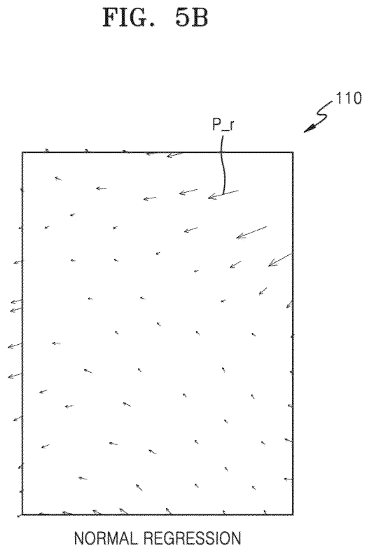

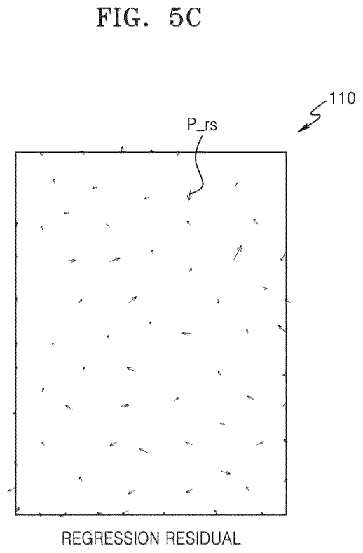

FIGS. 5A to 5C are graphs illustrating overlay correction when weight differentiation for each region of a pattern is not used.

FIG. 5A shows an example of collected overlay data of a field 110 of a wafer in operation S120 in FIG. 1. In the overlay data, an overlay P_o measured at a unit point is shown as an image. Referring to FIG. 5A, the field 110 may not be divided into a plurality of regions.

FIG. 5B illustrates a model in which an overlay of a pattern in the field 110 has been corrected. Because the field 110 is not divided into a plurality of regions, it is assumed that the same weight is applied to the entirety of the field 110. Thereafter, regression for overlay correction may be executed, and overlay correction may be performed on the pattern in the field 110 by using a derived correction parameter. In FIG. 5B, as an overlay correction model, an overlay value P_r at a unit point is shown as an image. The derived correction parameter may correspond to the correction parameter in Equation 5.

FIG. 5C illustrates overlay residual P_rs obtained by subtracting an overlay value in the overlay correction model of FIG. 5B from the overlay data of FIG. 5A.

Because the field 110 of the wafer is not divided into a plurality of regions in FIGS. 5A to 5C, and there is no weight differentiation, overlay correction may be executed using the correction parameter, which is derived through regression and expressed as Equation 5.

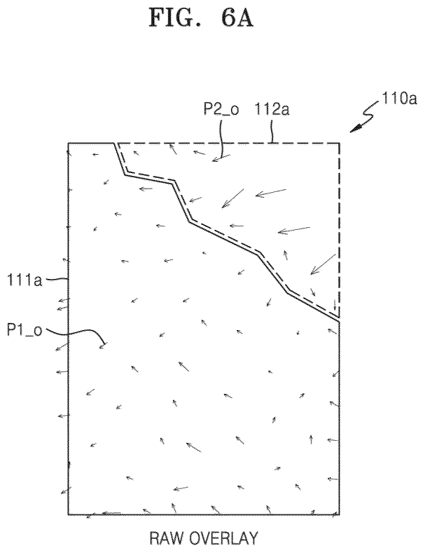

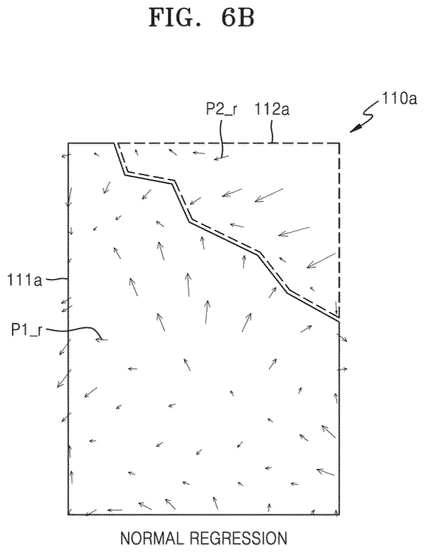

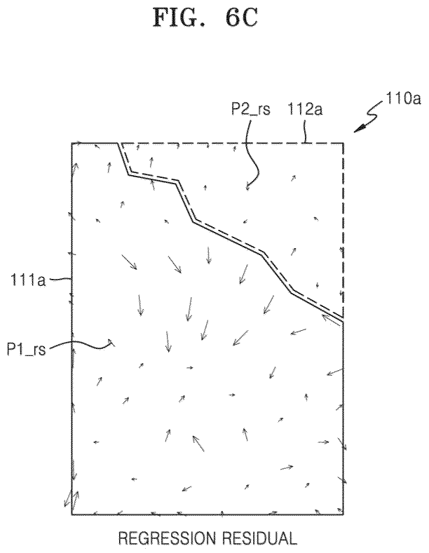

FIGS. 6A to 6C are graphs illustrating overlay correction when weight differentiation for each region of a pattern is used.

FIG. 6A shows an example of collected overlay data of the field 110a of a wafer in operation S120 in FIG. 1. Thereafter, the pattern of the field 110a may be divided into the first region 111a and the second region 112a in operation S131. For example, the first region 111a may be relatively close to the center of the top surface of the wafer, and the second region 112a may be relatively far from the center of the top surface of the wafer.

In FIG. 6A, a first overlay P1_o measured in a unit point of the first region 111a, and a second overlay P2_o measured in a unit point of the second region 112a are shown as images in overlay data.

FIG. 6B illustrates a model in which an overlay of a pattern in the field 110a has been corrected. Because the field 110a is divided into the first region 111a and the second region 112a, regression may be executed with different weights respectively applied to the first region 111a and the second region 112a of the field 110a. Thereafter, regression for overlay correction may be executed, and the overlay correction may be performed on the pattern in the field 110a by using a derived correction parameter. In FIG. 6B, as an overlay correction model, a first overlay value P1_r at a unit point of the first region 111a and a second overlay value P2_r at a unit point of the second region 112a are shown as images.

FIG. 6C illustrates overlay residual obtained by subtracting an overlay value in the overlay correction model of FIG. 6B from the overlay data of FIG. 6A. At this time, the overlay residual may include first overlay residual P1_rs in the first region 111a and second overlay residual P2_rs in the second region 112a.

Referring to FIGS. 6A to 6C, the field 110a of the wafer may be divided into a plurality of regions, i.e., the first region 111a and the second region 112a, and regression may be executed with different weights respectively applied to the first region 111a and the second region 112a. Overlay correction may be executed using the correction parameter, which is derived through the regression and expressed as Equation 2.

When comparing FIG. 5 with FIG. 6, it may be seen that overlay residual in the second region 112a having relatively large overlay data is effectively improved when weight differentiation is used.

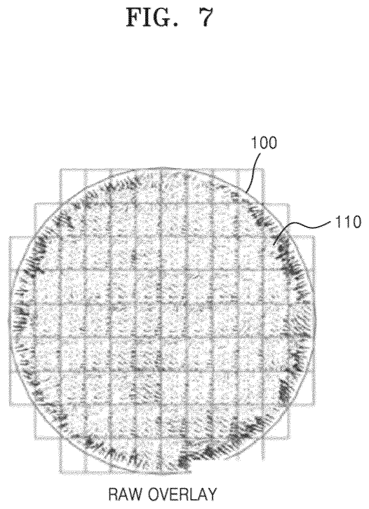

FIG. 7 is a diagram illustrating overlay data obtained by measuring an overlay of the wafer 100.

Referring to FIG. 7, the wafer 100 may be divided into a plurality of fields 110 in rows and columns. Referring to FIG. 7, it may be seen that overlay data is greater in an outer portion of the wafer 100 than in a central portion of the wafer 100.

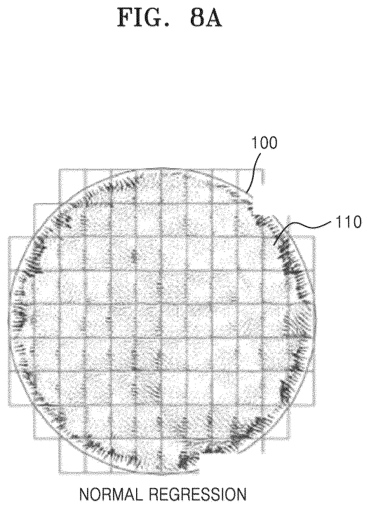

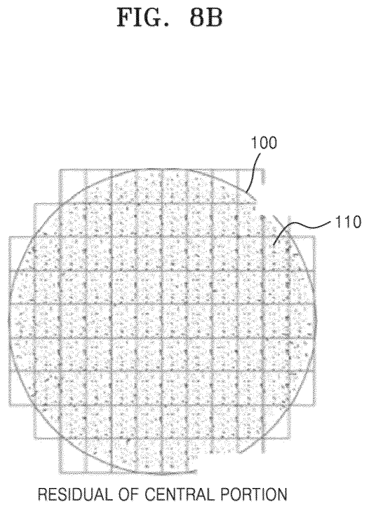

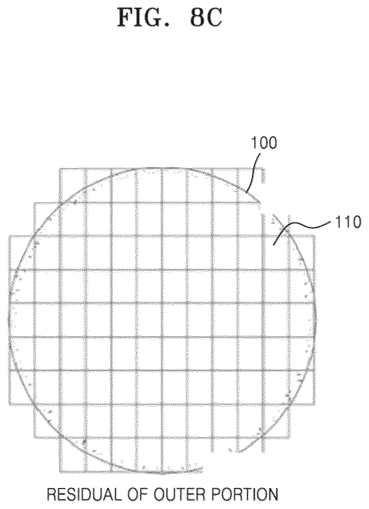

FIGS. 8A to 8C are diagrams illustrating overlay correction models when weight differentiation for each region of a pattern is not used.

FIG. 8A illustrates a model in which an overlay of a pattern in each of the fields 110 has been corrected. Because each of the fields 110 is not divided into a plurality of regions, it is assumed that the same weight is applied to the entirety of each field 110. Thereafter, regression for overlay correction may be executed, and overlay correction may be performed on the pattern in the field 110 by using a derived correction parameter. The derived correction parameter may correspond to the correction parameter in Equation 5.

FIGS. 8B and 8C illustrate overlay residual obtained by subtracting an overlay value in the overlay correction model of FIG. 8A from the overlay data of FIG. 7. In particular, FIG. 8B illustrates overlay residual in the remaining portion of the wafer 100 excluding the outer portion of the wafer 100, and FIG. 8C illustrates overlay residual in the outer portion of the wafer 100. Referring to FIG. 8C, it may be seen that overlay residual still remains in the outer portion of the wafer 100 when overlay correction is executed with the same weight applied to each of the fields 110.

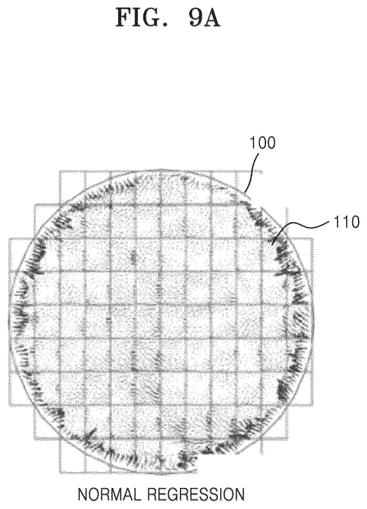

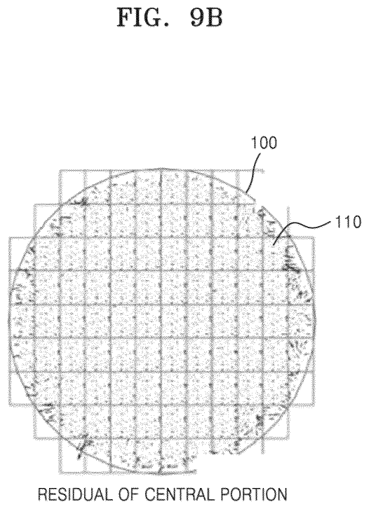

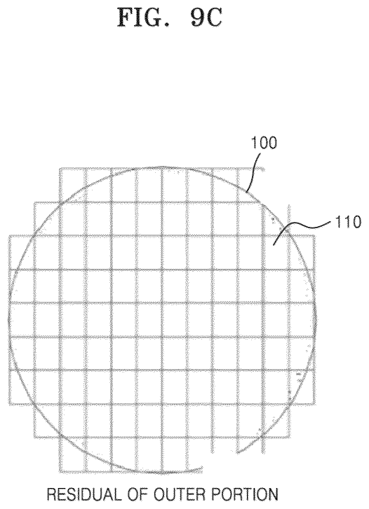

FIGS. 9A to 9C are diagrams illustrating overlay correction results when weight differentiation for each region of a pattern is used.

FIG. 9A illustrates a model in which an overlay of a pattern in each of the fields 110 has been corrected. Because each of the fields 110 is divided into a plurality of regions, regression may be executed with different weights respectively applied to the regions of each field 110. Thereafter, regression for overlay correction may be executed, and the overlay correction may be performed on the pattern in the field 110 by using a derived correction parameter. The derived correction parameter may correspond to the correction parameter in Equation 2.

FIGS. 9B and 9C illustrate overlay residual obtained by subtracting an overlay value in the overlay correction model of FIG. 9A from the overlay data of FIG. 7. In particular, FIG. 9B illustrates overlay residual in the remaining portion of the wafer 100 excluding the outer portion of the wafer 100, and FIG. 9C illustrates overlay residual in the outer portion of the wafer 100. Referring to FIG. 9C, it may be seen that overlay residual in the outer portion of the wafer 100 is effectively improved when regression is executed with different weights respectively applied to the regions of each of the fields 110.

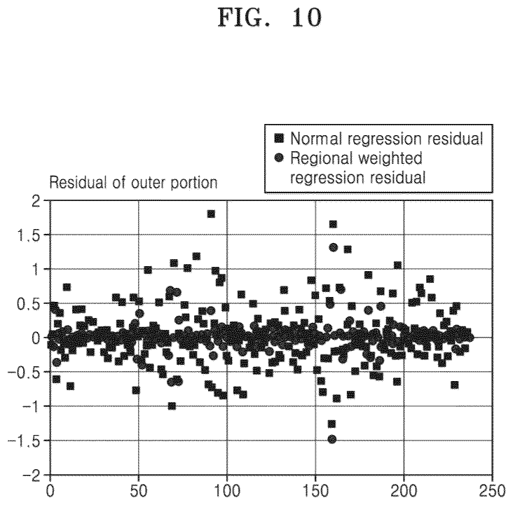

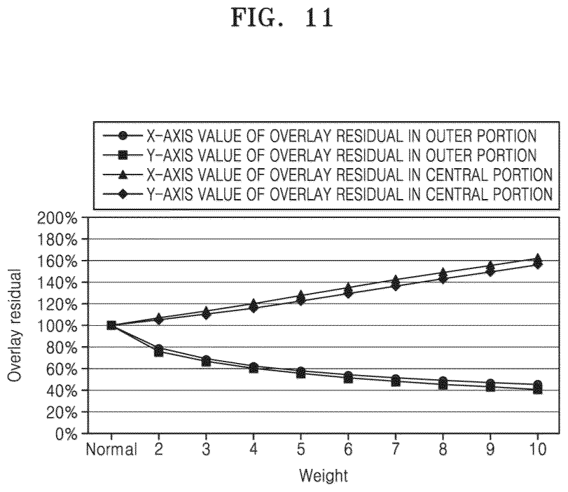

FIGS. 10 and 11 are graphs illustrating effects of a method of manufacturing a semiconductor device, according to an embodiment. For convenience of description, FIGS. 7 to 9C are also referred to.

FIG. 10 is a graph of the overlay residual in FIG. 8C and result values of the overlay residual in FIG. 9C. In particular, FIG. 10 illustrates the overlay residual of the outer portion of the wafer 100. The square dots in FIG. 10 correspond to the overlay residual in FIG. 8C and the circular dots correspond to the overlay residual in FIG. 9C.

In FIG. 10, the horizontal axis is the numbering of unit points and the vertical axis is relative value of overlay residual. When the vertical axis is positive, it means that the value of overlay data at a unit point is greater than an overlay value at the unit point in an overlay correction model. When the vertical axis is negative, it means that the value of overlay data at a unit point is less than an overlay value at the unit point in an overlay correction model. When the absolute value of a value on the vertical axis is large regardless of whether the vertical axis is positive or negative, it means that overlay residual is large.

Referring to FIG. 10, it may be seen that overlay residual in the outer portion of the wafer 100 is effectively improved when weight differentiation for each region of a pattern in each field 110 of the wafer 100 is used.

FIG. 11 is a graph showing the result values of the overlay residual in FIGS. 9B and 9C. In FIG. 11, a circular dot corresponds to the X-axis value of the overlay residual in FIG. 9C and a rectangular dot corresponds to the Y-axis value of the overlay residual in FIG. 9C. In FIG. 11, a triangular dot corresponds to the X-axis value of the overlay residual in FIG. 9B and a diamond dot corresponds to the Y-axis value of the overlay residual in FIG. 9B.

In FIG. 11, the horizontal axis is a weight for the outer region of the field 110 in the outer portion of the wafer 100. In other words, the weight for the outer region of the field 110 in the outer portion of the wafer 100 increases toward the right on the horizontal axis. Because weights for the respective regions of the field 110 are relative to each other, a weight for the central region of the field 110 may decrease when a weight for the outer region of the field 110 increases. In FIG. 11, the vertical axis is the value of overlay residual, and the unit of the vertical axis is percentages. When the vertical axis is 0%, it means that the overlay residual is 0. The absolute value of the overlay residual increases upwards on the vertical axis.

Referring to FIG. 11, it may be seen that the overlay residual of the outer portion in FIG. 9C decreases as the weight for the outer region of the field 110 in the outer portion of the wafer 100 increases on the horizontal axis. However, because weights for the respective regions of the field 110 are relative to each other, it may be seen that the overlay residual in the central portion of the wafer 100 in FIG. 9B increases as a weight for the central portion of the wafer 100 decreases.

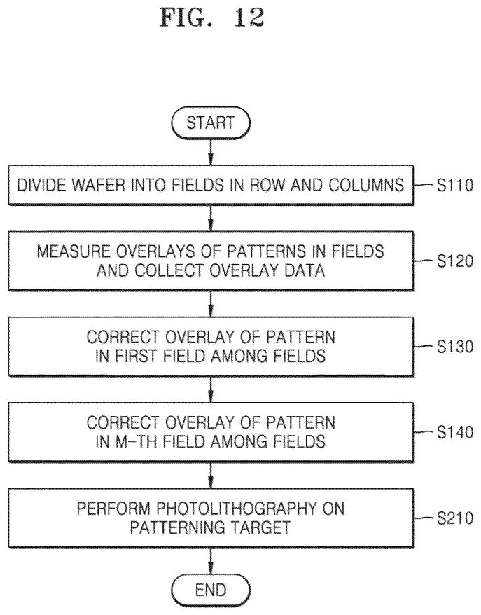

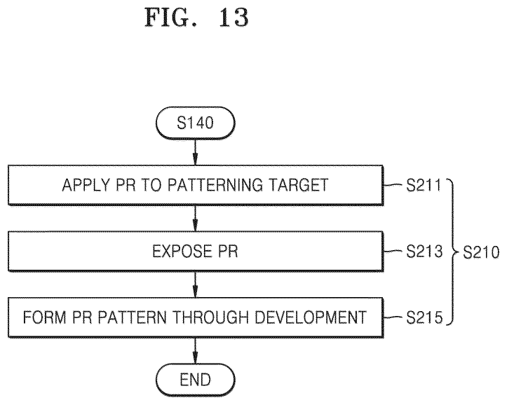

FIG. 12 is a flowchart of a method of manufacturing a semiconductor device, according to an embodiment. FIG. 13 is a detailed flowchart of an operation in the method of FIG. 12.

Referring to FIG. 12, the method of manufacturing a semiconductor device may sequentially include operations S110 to S140 from dividing a wafer into fields in rows and columns in operation S110 to correcting overlay of a pattern in an M-th field among the fields in operation S140. The detailed descriptions of operations S110 to S140 have been given above with reference to FIGS. 1 and 2.

Thereafter, the scanner (400 in FIG. 16) may perform photolithography on the patterning target (W in FIG. 16) in operation S210. The scanner 400 may execute overlay correction based on the first or second correction parameters during the photolithography. The photolithography may include several operations described below with reference to FIG. 13.

Referring to FIG. 13, the photolithography may include applying photoresist (PR), e.g., PR for EUV, to the patterning target W (in FIG. 16) in operation S211. For example, the PR may be applied to the patterning target W through spin coating.

After the PR application, the PR may be exposed through the scanner (400 in FIG. 16). The scanner 400 may include an EUV scanner and the PR may include PR for EUV. The scanner 400 may also execute overlay correction during exposure, based on the first or second correction parameters. The chemical properties of the PR may be changed through exposure. Due to the change in the chemical properties of the PR, an exposed or unexposed portion may be removed by subsequent development.

After the PR is exposed, a PR pattern may be formed through development in operation S215. Before the development, baking may be further executed. When a certain time period elapses after a developer is sprayed to the PR or the PR is dipped into the developer and then the pattern target W is rotated so that the developer is evenly spread over the PR during the development, the exposed or unexposed portion may be removed, as described above. Thereafter, cleaning and baking may be further executed.

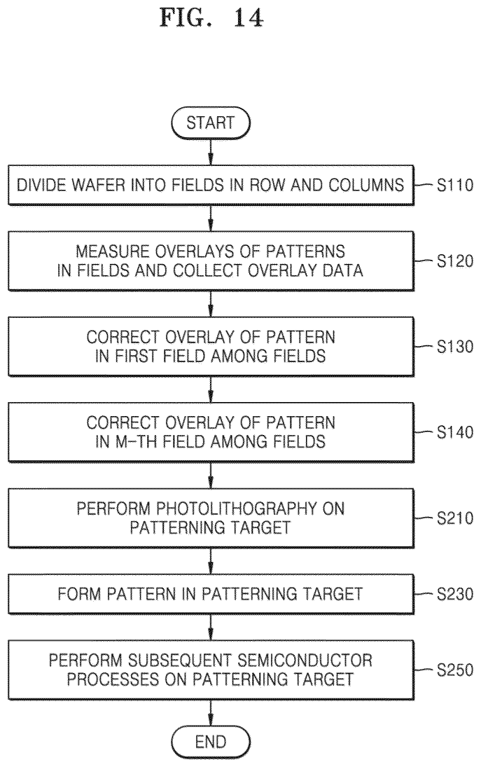

FIG. 14 is a flowchart of a method of manufacturing a semiconductor device. The descriptions given above with reference to FIGS. 12 and 13 are brief or omitted.

Referring to FIG. 14, the method of manufacturing a semiconductor device may sequentially include operations S110 to S210 from dividing a wafer into fields in rows and columns in operation S110 to performing photolithography on a patterning target in operation S210. The detailed descriptions of operations S110 to S210 have been given above with reference to FIGS. 1, 2, 12, and 13.

Thereafter, a pattern may be formed in the patterning target W (in FIG. 16) in operation S230. The pattern of the patterning target W may be formed by performing an etching process using the PR pattern, which is formed through the photolithography, as an etch mask. The etching process may be classified into dry etch and wet etch.

After the pattern is formed in the patterning target W (in FIG. 16), subsequent semiconductor processes may be performed on the patterning target W. By performing the subsequent semiconductor processes on the patterning target W (in FIG. 16), a semiconductor device may be manufactured. For example, when the patterning target W (in FIG. 16) is a wafer, a plurality of semiconductor devices may be manufactured from the wafer by performing subsequent semiconductor processes on the wafer.

The subsequent semiconductor processes on the wafer may include various processes. For example, the subsequent semiconductor processes on the wafer may include a vapor deposition process, an etching process, an ion process, and a cleaning process. The subsequent semiconductor processes on the wafer may include a wafer-level semiconductor device test. Furthermore, the subsequent semiconductor processes on the wafer may include a process of singulating the wafer into semiconductor chips and a process of packaging the semiconductor chips. The packaging process may refer to a process of mounting the semiconductor chips on a printed circuit board (PCB) and sealing the semiconductor chips with a sealing material and may include forming a stack package by stacking a plurality of semiconductor layers on the PCB or forming a package-on-package (POP) structure by stacking a stack package on a stack package. Through the packaging of semiconductor chips, a semiconductor device or a semiconductor package may be completely manufactured.

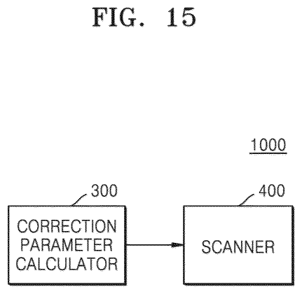

FIG. 15 is a block diagram of a scanner system according to an embodiment. FIG. 16 is a detailed block diagram of a scanner in FIG. 15. The descriptions given above with reference to FIGS. 1 to 14 are brief or omitted.

Referring to FIGS. 15 and 16, a scanner system 1000 may include a correction parameter calculator 300 and a scanner 400.

The correction parameter calculator 300 may calculate an overlay correction parameter through regression or regulated regression. The correction parameter calculator 300 may calculate overlay correction parameters through multiple stages, as described above with reference to FIGS. 1 and 2. For example, the correction parameter calculator 300 may calculate an overlay correction parameter by executing regression based on overlay data input to the correction parameter calculator 300. In particular, when it is determined that weight differentiation for each region of a pattern is necessary, the correction parameter calculator 300 may define weights for a plurality of regions of a field of a wafer and calculate a correction parameter including the weights.

Overlay data may be measured and collected by a measuring device. The collected overlay data may be automatically or manually input to the correction parameter calculator 300. For example, the correction parameter calculator 300 may be formed as an automatic process control (APC) device, to which overlay data is automatically input, or as an offline tool, such as a personal computer, to which overlay data is manually input by a user. When the correction parameter calculator 300 is formed as an APC device, calculated correction parameters may be automatically input to the scanner 400. When the correction parameter calculator 300 is formed as an offline tool, the calculated correction parameters may be manually input to the scanner 400 by a user or the offline tool may be connected to the scanner 400 so that the result of the offline tool may be automatically input to the scanner 400.

The scanner 400 may include an EUV scanner. However, the scanner 400 is not limited to the EUV scanner. For example, the scanner 400 may include an immersion scanner or an extended scanner. For convenience of description, the descriptions below focus on the EUV scanner. The scanner 400 may include an EUV light source 410, an illumination optical system 420, a projection optical system 430, a stage 440, and a mask support 450.

The EUV light source 410 may generate and output EUV light L1 having high energy density within a wavelength range of about 5 nm to about 50 nm. For example, the EUV light source 410 may generate and output the EUV light L1, which has high energy density and a wavelength of 13.5 nm. The EUV light source 410 may include a plasma-based light source or a synchrotron radiation light source. The plasma-based light source may generate plasma and use light emitted by the plasma and may include a laser-produced plasma (LPP) light source or a discharge-produced plasma (DPP) light source. In the scanner system 1000 of the present embodiment, the EUV light source 410 of the scanner 400 may be a plasma-based light source. In the scanner system 1000 of the present embodiment, the EUV light source 410 of the scanner 400 is not limited to a plasma-based light source. When the EUV light source 410 is a plasma-based light source, the EUV light source 410 may include a light condenser, such as an elliptical mirror and/or a spherical mirror, which concentrate EUV light to increase the energy density of illumination light incident to the illumination optical system 420.

The illumination optical system 420 may include a plurality of mirrors and transmit the EUV light L1 from the EUV light source 410 to an EUV mask M on the mask support 450. For example, the EUV light L1 from the EUV light source 410 may be reflected from mirrors of the illumination optical system 420 and incident to the EUV mask M on the mask support 450.

The EUV mask M may be formed as a reflective mask including a reflective region, a non-reflective region, and/or a semi-reflective region. The EUV mask M may include a pattern of a reflective multilayer film and an absorption layer. The reflective multilayer film may reflect EUV light and may be on a substrate, which includes a low thermal expansion coefficient material (LTEM) such as quartz, and the absorption layer may be on the reflective multilayer film. For example, the reflective multilayer film may have a structure in which a molybdenum (Mo) layers and silicon (Si) layers are alternately stacked in at least several tens of layers. For example, the absorption layer may include TaN, TaNO, TaBO, Ni, Au, Ag, C, Te, Pt, Pd, or Cr. However, the materials of the reflective multilayer film and the materials of the absorption layer are not limited to those described above. The absorption layer may correspond to the non-reflective and/or the semi-reflective region described above.

The EUV mask M may reflect the EUV light L1, which has been received through the illumination optical system 420, to the projection optical system 430. In detail, the EUV mask M may structure illumination light from the illumination optical system 420 into projection light based on the shape of the pattern, which is constituted of the reflective multilayer film on the substrate and the absorption layer, and may direct the projection light to the projection optical system 430. The projection light may be structured through at least second-order diffraction due to the pattern on the EUV mask M. The projection light may be incident to the projection optical system 430 while retaining shape information of the pattern on the EUV mask M, may pass through the projection optical system 430, and may transfer an image corresponding to the pattern of the EUV mask M to the patterning target W.

The patterning target W may include a substrate, e.g., a wafer, which includes a semiconductor material such as silicon. Hereinafter, unless specifically stated otherwise, the patterning target W and a wafer are used as the same concept, and accordingly, the wafer is also denoted by a reference character W. A target exposed to the projection light may be PR applied to the patterning target W.

The patterning target W may be disposed on the stage 440. The stage 440 may move in the X direction and the Y direction on the X-Y plane and in the Z direction that is perpendicular to the X-Y plane. Accordingly, the patterning target W may also move in the X, Y, and Z directions along with the movement of the stage 440.

The projection optical system 430 may include a plurality of mirrors. Although it is illustrated in FIG. 16 that the projection optical system 430 includes only two mirrors, i.e., a first mirror 432 and a second mirror 434, this is just for convenience of illustration. The projection optical system 430 may include more mirrors. For example, the projection optical system 430 may generally include four to eight mirrors. The number of mirrors included in the projection optical system 430 is not limited to the above numbers.

The scanner system 1000 of the present embodiment may include the correction parameter calculator 300 that may calculate correction parameters for an overlay through regression or regulated regression. Accordingly, the scanner system 1000 may calculate correction parameters, which maximize the correction capability of the scanner 400 within the correction limit of the scanner, through the correction parameter calculator 300 and may optimize overlay correction by executing the overlay correction based on the correction parameters by using the scanner 400. Consequently, the scanner system 1000 may greatly improve the overlay of a pattern formed on the patterning target W when the scanner 400 performs exposure of the patterning target W based on the correction parameters calculated by the correction parameter calculator 300.

While the disclosure has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
dividing a wafer into a plurality of fields, wherein the plurality of fields are arranged in rows and columns;
measuring an overlay error of a pattern in each of the plurality of fields and collecting overlay error data; and
correcting the overlay error of the pattern in a first field among the plurality of fields,
wherein the correcting the overlay error of the pattern in the first field comprises:
dividing the first field into a first region and a second region, wherein the second region has an overlay error that is greater than an overlay error of the first region;
comparing the overlay error of the first region with the overlay error of the second region;
defining a first weight for the first region and a second weight for the second region;
obtaining a correction parameter by executing regression using the overlay error data; and
providing the correction parameter to a scanner.

2. The method of claim 1, further comprising:
before the defining the first weight for the first region and the second weight for the second region, identifying whether the overlay error of the second region is greater than an overlay error limit; and
based on identifying that the overlay error of the second region is greater than the overlay error limit, performing the defining of the first weight for the first region and the second weight for the second region.

3. The method of claim 1, wherein a difference between the second weight and the first weight increases as a difference between the overlay error of the second region and the overlay error of the first region increases.

4. The method of claim 1, wherein the correction parameter is defined as
$$β = {( {w}_{1}^{2} {X}_{1}^{T} {X}_{1} + {w}_{2}^{2} {X}_{2}^{T} {X}_{2} )}^{- 1} ( {w}_{1}^{2} {X}_{1}^{T} {Y}_{1} + {w}_{2}^{2} {X}_{2}^{T} {Y}_{2} ) ,$$
where β is the correction parameter, X₁ is a first unit point in the first region, X₂ is a second unit point in the second region, w₁ is the first weight, w₂ is the second weight, Y₁ is an overlay error at the first unit point, and Y₂ is an overlay error at the second unit point.

5. The method of claim 1, wherein the scanner comprises an extreme ultraviolet scanner.

6. The method of claim 1, wherein the defining the first weight for the first region and the second weight for the second region is performed by an automatic process control (APC) system or an offline tool, and
wherein data is automatically input to the APC system and the data is input to the offline tool by a user.

7. The method of claim 1, wherein the first field comprises a plurality of unit points,
wherein the first region comprises one or more of the plurality of unit points, and the second region comprises one or more unit points not included in the first region from among the plurality of unit points, and
wherein each of the plurality of unit points is a minimum point at which the overlay error is measured.

8. The method of claim 7, wherein an outermost of the one or more unit points of the first region are respectively in contact with an outermost of the one or more unit points of the second region.

9. The method of claim 1, wherein the second weight is greater than the first weight, and
wherein the overlay error of the second region is greater than the overlay error of the first region.

10. The method of claim 1, further comprising:
after the correcting the overlay error of the pattern in the first field, correcting the overlay error of the pattern in a second field among the plurality of fields.

11. A method of manufacturing a semiconductor device, the method comprising:
dividing a wafer into a plurality of fields, wherein the plurality of fields are arranged in rows and columns;
measuring an overlay error of a pattern in each of the plurality of fields and collecting overlay error data; and
correcting the overlay error of the pattern in a first field among the plurality of fields,
wherein the correcting of the overlay error of the pattern in the first field comprises:
dividing the first field into N regions, where N is an integer of at least 2;
comparing overlay errors of the N regions with each other;
defining N weights for the N regions, respectively;
obtaining a first correction parameter by executing regression using the overlay error data; and
providing the first correction parameter to a scanner.

12. The method of claim 11, further comprising:
after the correcting the overlay error of the pattern in the first field, performing photolithography, by the scanner, on a patterning target based on the first correction parameter.

13. The method of claim 12, wherein the scanner comprises an extreme ultraviolet (EUV) scanner, and
wherein the performing photolithography comprises:
applying EUV photoresist to the patterning target;
exposing the EUV photoresist using the scanner; and
forming a photoresist pattern by developing the EUV photoresist.

14. The method of claim 11, wherein the first correction parameter is defined as
$${β}_{1} = {( {\sum }_{i = 1}^{n} {w}_{i}^{2} {X}_{i}^{T} {X}_{i} )}^{- 1} ( {\sum }_{i = 1}^{n} {w}_{i}^{2} {X}_{i}^{T} {Y}_{i} ) ,$$
where β₁ is the first correction parameter, n is equal to N, Xᵢ is an i-th unit point in an i-th region of the first field, wᵢ is an i-th weight, and Yᵢ is an overlay error at the i-th unit point.

15. The method of claim 11, further comprising:
before the defining the N weights, identifying whether the overlay error of at least one of the N regions is greater than an overlay error limit; and
based on identifying that the overlay error of the at least one of the N regions is greater than the overlay error limit, performing the defining of the N weights.

16. The method of claim 15, further comprising:
based on the overlay error of any one of the N regions being less than or equal to the overlay error limit, calculating a second correction parameter by executing regression using the overlay error data,
wherein the second correction parameter is defined as
$${β}_{2} = {( {X}^{T} X )}^{- 1} ( {X}^{T} Y ) ,$$
where β₂ is the second correction parameter, X is a unit point in the first field, and Y is an overlay error at the unit point.

17. The method of claim 11, further comprising:
after the correcting the overlay error of the pattern in the first field, correcting the overlay error of the pattern in a second field among the plurality of fields.

18. The method of claim 11, wherein the defining the N weights is performed by an automatic process control (APC) system or an offline tool, and
wherein data is automatically input to the APC system and the data is input to the offline tool by a user.

19. A method of manufacturing a semiconductor device, the method comprising:
dividing a wafer into a plurality of fields, wherein the plurality of fields are arranged in rows and columns;
measuring an overlay error of a pattern in each of the plurality of fields and collecting overlay error data; and
correcting the overlay error of the pattern in a first field among the plurality of fields,
wherein the correcting the overlay error of the pattern in the first field comprises:
dividing the first field into a first region and a second region, wherein the second region has an overlay error that is greater than an overlay error of the first region;
identifying whether the overlay error of the second region is greater than an overlay error limit;
based on identifying that the overlay error of the second region is greater than the overlay error limit, comparing the overlay error of the first region with the overlay error of the second region and defining a first weight for the first region and a second weight for the second region;
obtaining a first correction parameter by executing regression using the overlay error data; and
providing the first correction parameter to a scanner, and
wherein the first correction parameter is defined as
$${β}_{1} = {( {w}_{1}^{2} {X}_{1}^{T} {X}_{1} + {w}_{2}^{2} {X}_{2}^{T} {X}_{2} )}^{- 1} ( {w}_{1}^{2} {X}_{1}^{T} {Y}_{1} + {w}_{2}^{2} {X}_{2}^{T} {Y}_{2} ) ,$$
where β₁ is the first correction parameter, X₁ is a first unit point in the first region, X₂ is a second unit point in the second region, w₁ is the first weight, w₂ is the second weight, Y₁ is an overlay error at the first unit point, and Y₂ is an overlay error at the second unit point.

20. The method of claim 19, further comprising:
based on identifying that the overlay error of the second region is less than or equal to the overlay error limit, obtaining a second correction parameter by executing regression using the overlay error data,
wherein the second correction parameter is defined as
$${β}_{2} = {( {X}^{T} X )}^{- 1} ( {X}^{T} Y ) ,$$
where β₂ is the second correction parameter, X is a unit point in the first field, and Y is an overlay error at the unit point.
